(19) United States
(12) Patent Application Publication
(10) Pub. No.: US 2025/0040209 A1
(43) Pub. Date: Jan. 30, 2025

(54) ARTIFICIAL DOUBLE-LAYER TWO-DIMENSIONAL MATERIAL AND METHOD OF MANUFACTURING SAME

(71) Applicant: NATIONAL CENTRAL UNIVERSITY, Taoyuan City (TW)

(72) Inventors: CHING-YUAN SU, Taoyuan City (TW); REN-KUEI LIAO, Taoyuan City (TW)

(21) Appl. No.: 18/915,342

(22) Filed: Oct. 14, 2024

Related U.S. Application Data
(63) Continuation-in-part of application No. 17/729,872, filed on Apr. 26, 2022.
(63) Continuation-in-part of application No. 17/730,073, filed on Apr. 26, 2022.
(63) Continuation-in-part of application No. 17/730,094, filed on Apr. 26, 2022.
(60) Provisional application No. 63/252,816, filed on Oct. 6, 2021.

(30) Foreign Application Priority Data
Mar. 8, 2024 (TW) 113108478

(51) Int. Cl. H01L 29/15; H01L 29/76

(52) U.S. Cl. CPC H01L 29/151; H01L 29/7606

(57) ABSTRACT

An artificial double-layer two-dimensional material includes a first layered atomic structure and a second layered atomic structure. The first layered atomic structure includes a first middle atomic layer, a first lower atomic layer, and a first upper atomic layer. The first lower and the first upper atomic layers are disposed on lower and upper surfaces of the first middle atomic layer respectively. The second layered atomic structure includes a second middle atomic layer, a second lower atomic layer, and a second upper atomic layer. The second lower and the second upper atomic layers are disposed on lower and upper surfaces of the second middle atomic layer respectively. The first middle atomic layer and the second middle atomic layer are two-dimensional planar atomic structures formed of transition metals. The first lower and the first upper atomic layers are 2D planar atomic structures formed of heterogeneous atom.

### CROSS REFERENCE TO RELATED APPLICATIONS

The present invention is a continuation-in-part application of U.S. Non-Provisional patents application Ser. Nos. 17/729,872 filed on Apr. 26, 2022, 17/730,073 filed on Apr. 26, 2022 and 17/730,094 filed on Apr. 26, 2022, all of which claim benefit of U.S. Provisional Patent Application Nos. 63/252,816 filed on Oct. 6, 2021, the same disclosures of which are also respectively filed in Taiwan Intellectual Property Office as Taiwan Application Nos. 111106669 on Feb. 24, 2022, 111106668 on Feb. 24, 2022 and 111106667 on Feb. 24, 2022, and the present invention further claims benefit of Taiwan Application No. 113108478 on Mar. 8, 2024 filed in Taiwan Intellectual Property Office, the disclosure of which is incorporated by reference herein.

### BACKGROUND OF THE INVENTION

### 1. Technical Field

The technical field relates to a two-dimensional (2D) material, and more particularly relates to an artificial double-layer 2D material and a method of manufacturing the same.

### 2. Description of Related Art

Electronic components are typically Si based electronic components. However, sizes of the electronic components are decreased gradually due to scaling down. It is estimated that miniaturization of the electronic components may reach its limit in a near future. Further, heat dissipation, leakage current, noise and interference are issued to be addressed due to the miniaturization of the electronic components. For solving the issues, a new material or element structure is required and it is supposed to deal with, particularly miniaturization processes, gate control of semiconductor, and conductive properties of semiconductor including movement of carriers in semiconductors. It is known that graphene having zero band gap used in electronic components has drawbacks particularly in logic circuits. 2D materials such as transition metal dichalcogenides (TMDs) including molybdenum disulfide (MoS₂), tungsten disulfide (WS₂), tungsten diselenide (WSe₂), and indium (II) selenide (InSe) have excellent electrical properties and different energy gaps and thus have a great potential to become a next generation semiconductor material. In detail, TMDs have excellent thermal conduction, electronic, optical and mechanical properties similar to that of grapheme. Further, TMDs have an energy gap not possessed by graphene. It is widely believed that TMDs will become a candidate material for 3 nm process in semiconductor manufacturing.

It is understood that such 2D materials for manufacturing semiconductors should have acceptable energy gaps, high carrier mobility, high on-current current ratio, low energy consumption, high integration, and high reliability. Thus, there are many problems to be solved prior to mass production. These problems include controllability of large area synthesis, wafer level transfer, contact resistance, and reliability analysis of components. Particularly, the 2D materials are required to be compatible with current semiconductor manufacturing processes including extreme ultraviolet (EUV) radiation used in photolithography, patterns, metallic processes, and deposition and annealing of high-K materials. Factors including EUV photons used in photolithography capable of penetrating photoresist to damage the 2D material, and impact and reliability of electronic components made of conventional 2D material should be taken into consideration in the development of new 2D materials.

For applications of the 2D material, the scalable production of large-area, continuous, high-quality MoS₂ on dielectrics is a prerequisite. The use of mechanical exfoliation provides the purest MoS₂ with the highest quality, albeit with size limitations. Chemical vapor deposition (CVD) methods for MoS₂ (CVD-MoS₂) typically may manufacture multilayers of MoS₂, but the uniformities of the films are not good, resulting in low field-effect mobility. Surface-treated synthesized continuous MoS₂ films also exhibit very low field-effect mobilities (0.02-7 cm²/Vs). Currently, achieving continuous MoS₂ films on SiO₂ and precise control over the thickness and layer number for synthesizing wafer-scale high-quality 2D materials remains a critical challenge.

### SUMMARY OF THE INVENTION

The disclosure is directed to an artificial double-layer 2D material having excellent physical and chemical properties for manufacturing semiconductors, compared to a single-layer 2D material in order to eliminate drawbacks including those associated with the conventional art. The disclosure is further directed to a method of manufacturing an artificial 2D material by utilizing a novel 2D material synthesis platform and a precise control of atom layers removal.

It is therefore one object of the invention to provide an artificial double-layer two-dimensional material, comprising a first layered atomic structure and a second layered atomic structure; wherein the first layered atomic structure comprises a first middle atomic layer, a first lower atomic layer, and a first upper atomic layer, the first lower and the first upper atomic layers are disposed on lower and upper surfaces of the first middle atomic layer respectively; the first middle atomic layer is a two-dimensional (2D) planar atomic structure formed of a transition metal; the first lower and the first upper atomic layers are 2D planar atomic structures formed of heterogeneous atoms; wherein the second layered atomic structure comprises a second middle atomic layer, a second lower atomic layer, and a second upper atomic layer, the second lower and the second upper atomic layers are disposed on lower and upper surfaces of the second middle atomic layer respectively; the second middle atomic layer is a two-dimensional (2D) planar atomic structure formed of a transition metal; wherein atoms of the first layered atomic structure and the second layered atomic structure are bound by chemical bonding; and the first layered atomic structure and the second layered atomic structure are bound by van der Waals forces.

In one of the exemplary embodiments, the transition metal is selected from the group consisting of tungsten (W), molybdenum (Mo), titanium (Ti), platinum (Pt), indium (In), tin (Sn), niobium (Nb), and tantalum (Ta).

In one of the exemplary embodiments, the first lower atomic layer, the second lower atomic layer and the second upper atomic layer are formed of sulfur, selenium, or tellurium.

In one of the exemplary embodiments, the first upper atomic layer includes a plurality of metal atoms.

In one of the exemplary embodiments, the metal of the first upper atomic layer is selected from the group consisting of nickel, tungsten, copper, titanium, palladium, bismuth, antimony, scandium, vanadium, gold, and platinum.

In one of the exemplary embodiments, further comprises an outer atomic layer disposed on the first upper atomic layer, the outer atomic layer being bound by metallic bonding and the outer atomic layer including a plurality of metal atoms.

In one of the exemplary embodiments, the metal of the outer atomic layer is selected from the group consisting of cobalt, nickel, tungsten, copper, titanium, palladium, bismuth, antimony, scandium, vanadium, gold, and platinum.

In one of the exemplary embodiments, the chemical element of the first upper atomic layer is selected from the group consisting of carbon, oxygen, nitrogen, fluorine, chlorine, and phosphorus.

In one of the exemplary embodiments, further comprises an outer atomic layer disposed on the first upper atomic layer, the outer atomic layer including a plurality of metal atoms.

In one of the exemplary embodiments, the metal of the outer atomic layer is selected from the group consisting of cobalt, nickel, tungsten, copper, titanium, palladium, bismuth, antimony, scandium, vanadium, gold, and platinum.

In one of the exemplary embodiments, the artificial 2D material does not belong to the metallic properties (1T phase phase).

A method for manufacturing the artificial double-layer two-dimensional material is provided in the invention, comprising the steps of: providing at least two artificial two-dimensional materials each having a layered atomic structure; stacking the two-dimensional materials each having a layered atomic structure to form a double-layer two-dimensional material having a two-layered atomic structure; placing the double-layer two-dimensional material in a vacuum; removing an atomic layer on one surface of the double-layer 2D material to expose unsaturated compounds by means of plasma; introducing heterogeneous atoms into the vacuum wherein the heterogeneous atoms are different from atoms on the other surface of the double-layer material; and binding the heterogeneous atoms with the unsaturated compounds to form an artificial double-layer 2D material having two heterogeneous junctions.

A field-effect transistor having an artificial double-layer 2D material is provided in the invention, comprising: a substrate having an oxide layer, the artificial double-layer 2D material as described above, a first metallic electrode and a second metallic electrode; wherein the artificial double-layer 2D material is on the substrate; wherein the first upper atomic is heterogeneous and comprises a first heterogeneous zone and a second heterogeneous zone; the first and second heterogeneous zones each is a metal atomic layer; wherein the first metallic electrode is electrically connected to the metal atomic layer of the first heterogeneous zone by means of metallic bonding and the second metallic electrode is electrically connected to the metal atomic layer of the second heterogeneous zone by means of metallic bonding respectively.

In one of the exemplary embodiments, the metal contact of the interface between the first metallic electrode and the first heterogeneous zone, as well as between the second metallic electrode and the second heterogeneous zone are carrier doping regions.

In one of the exemplary embodiments, the metal contact of the interface between the first metallic electrode and the first heterogeneous zone, as well as between the second metallic electrode and the second heterogeneous zone match the electronic structure of the first middle atomic layer, reducing the resistance of carrier injection.

In one of the exemplary embodiments, the metal contact of the interface between the first metallic electrode and the first heterogeneous zone, as well as between the second metallic electrode and the second heterogeneous zone, form dipole internal electric fields, reducing the resistance of carrier injection.

The above and other objects, features and advantages of the invention will become apparent from the following detailed description taken with the accompanying drawings.

### BRIEF DESCRIPTION OF THE DRAWINGS

FIG. 1 is a longitudinal sectional view of an artificial 2D material according to a first preferred embodiment of the invention;

FIG. 2 is a longitudinal sectional view of an artificial 2D material according to a second preferred embodiment of the invention;

FIG. 3 is a longitudinal sectional view of an artificial 2D material according to a third preferred embodiment of the invention;

FIG. 4 is a longitudinal sectional view of an artificial 2D material according to a fourth preferred embodiment of the invention;

FIG. 5 is an illustration of a crystal structure of an artificial double-layer 2D material according to a fifth preferred embodiment of the invention;

FIG. 6 is an illustration of a crystal structure of an artificial double-layer 2D material according to a sixth preferred embodiment of the invention;

FIG. 7 is an illustration of a crystal structure of an artificial double-layer 2D material according to a seventh preferred embodiment of the invention;

FIG. 8 is an illustration of a crystal structure of an artificial double-layer 2D material according to an eighth preferred embodiment of the invention;

FIG. 9 is a block diagram of a synthesis platform for the artificial 2D material/the artificial double-layer 2D material;

FIG. 10 is a flow chart of a method of manufacturing an artificial 2D material according to the invention using the synthesis platform, the artificial 2D material being that described in the first, second, third, and fourth preferred embodiments;

FIG. 11 is a flow chart of a method of manufacturing a double-layer artificial 2D material according to the invention using the synthesis platform, the artificial double-layer 2D material being that described in the fifth, sixth, seventh and eighth preferred embodiments;

FIG. 12 plots Raman shift versus intensity for the artificial 2D material using hydrogen plasma and not using hydrogen plasma according to the invention;

FIG. 13 is a longitudinal sectional view of the artificial 2D material of the invention showing a monolayer having a plurality of heterogeneous junctions according to a ninth preferred embodiment of the invention;

FIG. 14 is a top plan view of FIG. 13;

FIG. 15 is a schematic longitudinal sectional view of an electronic component (e.g., field-effect transistor (FET)) according to a first configuration of the invention, the electronic component incorporating the artificial 2D material of the invention;

FIG. 16 is a schematic longitudinal sectional view of an electronic component (e.g., back-gated (FET)) according to a second configuration of the invention, the electronic component incorporating the artificial 2D material of the invention;

FIG. 17 is a schematic longitudinal sectional view of an electronic component according to a third configuration of the invention, the electronic component incorporating the artificial 2D material of the invention;

FIG. 18 plots V_{G}(V) versus I_{DS}(A) for an electronic component formed of artificial 2D material of the first preferred embodiment of the invention with or without treatment as comparison;

FIG. 19 in part (a) plots V_{G}(V) versus I_{DS}(A) for an electronic component formed of artificial 2D material of the first preferred embodiment of the invention without plasma treatment; and in part (b) plots V_{G}(V) versus I_{DS}(A) for an electronic component formed of artificial 2D material of the first preferred embodiment of the invention with plasma treatment;

FIG. 20 shows the molybdenum-to-sulfur ratio of the artificial double-layer 2D material treated with hydrogen plasma at different times according to the present invention;

FIG. 21 is an illustration of a crystal structure of the artificial double-layer 2D material having a plurality of heterogeneous junctions according to a tenth preferred embodiment of the invention;

FIG. 22 is a top plan view of FIG. 21;

FIG. 23 is a schematic longitudinal sectional view of an electronic component (e.g., field-effect transistor (FET)) according to a fourth configuration of the invention, the electronic component incorporating the artificial double-layer 2D material of the invention;

FIG. 24 is a schematic longitudinal sectional view of an electronic component (e.g., back-gated (FET)) according to a fifth configuration of the invention, the electronic component incorporating the artificial double-layer 2D material of the invention;

FIG. 25 is a schematic longitudinal sectional view of an electronic component according to a sixth configuration of the invention, the electronic component incorporating the artificial double-layer 2D material of the invention;

FIG. 26. plots gate voltage (V) versus drain current density (A/um) for an electronic component formed of artificial 2D material of the invention with or without plasma treatment as comparison.

### DETAILED DESCRIPTION OF THE INVENTION

Embodiments of the invention will now be described, by way of example only, with reference to the accompanying drawings.

In the invention, each layer of a layered atomic structure is a 2D planar atomic layer and is schematically shown in the drawings. Each layer has a thickness but the invention is not limited to such. The atomic layer of the 2D plane means a monolayer. In the invention, upper, lower, first, second and third are used to show relative locations of different elements and are for ease of illustration. The invention does not aim to limit the elements to such locations.

In a first preferred embodiment of the invention, an artificial 2D material having two heterogeneous junctions is described. Synthesis platform is used to break two homogeneous surfaces (i.e., MXX in which M is transition metal and X means sulfide) of a TMD and form two heterogeneous surfaces (i.e., MXY in which M is transition metal, X means a first chalcogen element and Y means a second chalcogen element different from the first one) of the TMD. Physical and chemical properties of the artificial 2D material having two heterogeneous junctions are more advantageous than that of the artificial 2D material having two homogeneous junctions of the conventional art. These properties include increased energy gap controllability in comparison with the conventional TMDs and increased conduction capability in comparison with the conventional 2D material having two homogeneous junctions.

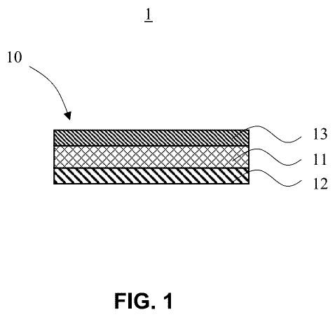

Referring to FIG. 1, an artificial 2D material 1 in accordance with a first preferred embodiment of the invention comprises a layered atomic structure 10 including a middle atomic layer 11, a lower atomic layer 12 and an upper atomic layer 13 in which the lower atomic layer 12 and the upper atomic layer 13 are disposed on lower and upper surfaces of the middle atomic layer 11 respectively; the middle atomic layer 11 is a 2D planar atomic structure formed of a transition metal selected from the group consisting of titanium (Ti), vanadium (V), chromium (Cr), manganese (Mn), iron (Fe), cobalt (Co), nickel (Ni), copper (Cu), tin (Sn), zinc (Zn), zirconium (Zr), niobium (Nb), molybdenum (Mo), cadmium (Cd), hafnium (Hf), platinum (Pt), tantalum (Ta), tungsten (W), and rhenium (Re); and the lower atomic layer 12 and the upper atomic layer 13 are formed of sulfur, selenium, or tellurium. In the embodiment, the artificial 2D material 1 is a 2D crystalline material. The lower atomic layer 12 and the upper atomic layer 13 are a 2D planar atomic structure formed of heterogeneous atoms. Atoms of the layered atomic structure 10 are bound by chemical bonding.

A Schottky barrier is a potential energy barrier for electrons formed at a metal-semiconductor junction. Schottky barriers have rectifying characteristics, suitable for use as a diode. The Schottky barrier is fixed relative to the metal's Fermi level. A phenomenon referred to as “Fermi level pinning” caused some point of the band gap, at which finite DOS exists, to be locked (pinned) to the Fermi level. These factors affect electrical impedance. Electrical impedance is an issue to be addressed in electronic components formed of 2D material. It is desired to decrease electrical impedance between channels and electrodes of a semiconductor formed of 2D material to a value less than 100 μΩ.

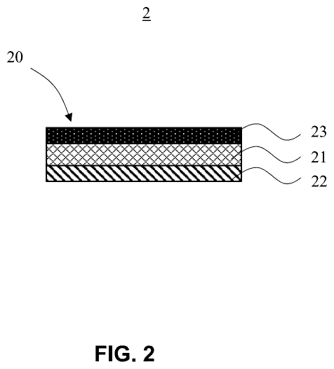

Referring to FIG. 2, an artificial 2D material 2 in accordance with a second preferred embodiment of the invention is shown. The characteristics of the second preferred embodiment are substantially the same as that of the first preferred embodiment except the following: the artificial 2D material 2 comprises a layered atomic structure 20 including a middle atomic layer 21, a lower atomic layer 22 and an upper atomic layer 23 in which the lower atomic layer 22 and the upper atomic layer 23 are disposed on lower and upper surfaces of the middle atomic layer 21 respectively; the middle atomic layer 21 is a 2D planar atomic structure formed of a transition metal selected from the group consisting of titanium (Ti), vanadium (V), chromium (Cr), manganese (Mn), iron (Fe), cobalt (Co), nickel (Ni), copper (Cu), tin (Sn), zinc (Zn), zirconium (Zr), niobium (Nb), molybdenum (Mo), cadmium (Cd), hafnium (Hf), platinum (Pt), tantalum (Ta), tungsten (W), and Rhenium (Re); and the lower atomic layer 22 and the upper atomic layer 23 are formed of sulfur, selenium, or tellurium. In the embodiment, the artificial 2D material 2 is a 2D crystalline material. The lower atomic layer 22 and the upper atomic layer 23 are a 2D planar atomic structure formed of heterogeneous atoms. Atoms of the middle atomic layer 21 and the upper atomic layer 23 are bound by metallic bonding. As a result, an artificial 2D alloy material having a first metal-transition metal-sulfur junction structure, i.e., two heterogeneous junctions are formed.

In the embodiment, the artificial 2D alloy material having two heterogeneous junctions is formed by synthesis. In detail, metals are introduced into the artificial 2D material to change its junctions of sulfide-transition metal-sulfide to junctions of transition metal(M)-sulfide(X)-metal(Z) (MXZ) by synthesis. As a result, an artificial 2D alloy material is formed. The artificial 2D alloy material has advantages including improved electrical characteristics, improved energy gap adjustment, lower contact resistance and increased on-state current in comparison with the conventional artificial 2D material having junctions of sulfide-transition metal-sulfide.

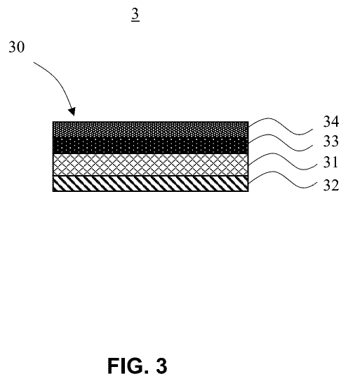

Referring to FIG. 3, an artificial 2D material 3 in accordance with a third preferred embodiment of the invention is shown. The third preferred embodiment aims to meet the demands of more 2D material applications and advanced semiconductor manufacturing processes including depositing metal layer. The characteristics of the third preferred embodiment are substantially the same as that of the second preferred embodiment except the following: the artificial 2D material 3 comprises a layered atomic structure 30 including a middle atomic layer 31, a lower atomic layer 32, an upper atomic layer 33 and an outer atomic layer 34 on the upper atomic layer 33 in which the lower atomic layer 32 and the upper atomic layer 33 are disposed on lower and upper surfaces of the middle atomic layer 31 respectively; the middle atomic layer 31 is a 2D planar atomic structure formed of a transition metal selected from the group consisting of titanium (Ti), vanadium (V), chromium (Cr), manganese (Mn), iron (Fe), cobalt (Co), nickel (Ni), copper (Cu), tin (Sn), zinc (Zn), zirconium (Zr), niobium (Nb), molybdenum (Mo), cadmium (Cd), hafnium (Hf), platinum (Pt), tantalum (Ta), tungsten (W), and Rhenium (Re); the lower atomic layer 32 is formed of sulfur, selenium, or tellurium; the upper atomic layer 33 is a first metal layer formed of a metal selected from the group consisting of nickel (Ni), tungsten (W), copper (Cu), bismuth (Bi), scandium (Sc), vanadium (V), titanium (Ti) and platinum (Pt); and the outer atomic layer 34 is a second metal layer formed of a metal selected from the group consisting of cobalt (Co), nickel (Ni), tungsten (W), copper (Cu), bismuth (Bi), titanium (Ti), scandium (Sc), vanadium (V), antimony (Sb), gold (Au) and platinum (Pt).

In the embodiment, the artificial 2D material 3 is a 2D crystalline material. The lower atomic layer 32 and the upper atomic layer 33 are a 2D planar atomic structure formed of heterogeneous atoms. Atoms of the middle atomic layer 31 and the upper atomic layer 33 are bound by metallic bonding. As a result, an artificial 2D alloy material having a second metal (or first metal)-transition metal-sulfur junction structure, i.e., two different junctions is formed.

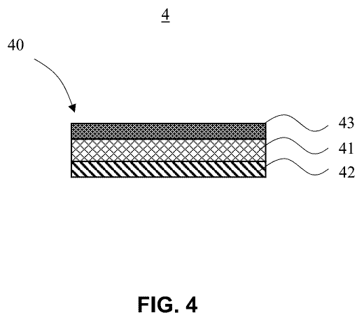

Referring to FIG. 4, an artificial 2D material 4 in accordance with a fourth preferred embodiment of the invention is shown. The characteristics of the fourth preferred embodiment are substantially the same as that of the first preferred embodiment except the following: the artificial 2D material 4 comprises a layered atomic structure 40 including a middle atomic layer 41, a lower atomic layer 42, and an upper atomic layer 43 in which the upper atomic layer 43 is formed of oxygen (O), phosphor (P), nitrogen (N), chlorine (Cl), carbon (C), or fluorine (F). In the embodiment, the artificial 2D material is a 2D compound material. Taking oxygen atoms as an example, an artificial 2D compound material having an oxygen-transition metal-sulfur junction structure, i.e., two heterogeneous junctions is formed.

In a fifth preferred embodiment of the invention, an artificial double-layer 2D material including a layered atomic structure material with two heterogeneous junctions is described. Synthesis platform provided in the invention is used to break two homogeneous surfaces (i.e., MXX in which M is transition metal and X means sulfide) of a TMD and form two heterogeneous surfaces (i.e., MXY in which M is transition metal, X means a first chalcogen element and Y means a second chalcogen element different from the first one) of the TMD. Physical and chemical properties of the artificial 2D material having two heterogeneous junctions are more advantageous than that of the artificial 2D material having two homogeneous junctions of the conventional art. These properties include increased energy gap controllability in comparison with the conventional TMDs and increased conduction capability in comparison with the conventional 2D material having two homogeneous junctions. In comparison to monolayer 2D materials, the electrical properties of double-layer 2D materials are superior, particularly in on-current and field-effect mobility.

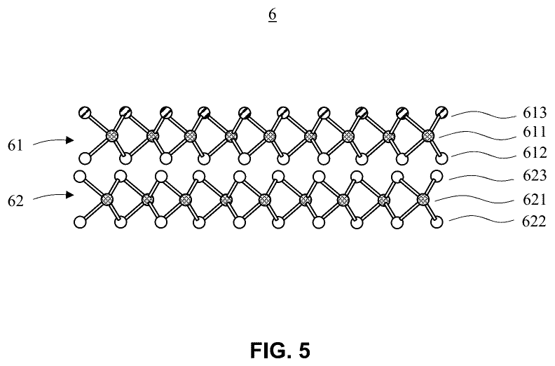

Referring to FIG. 5, an artificial double-layer 2D material 6 in accordance with a fifth preferred embodiment of the invention comprises a first layered atomic structure 61 and a second layered atomic structure 62. The first layered atomic structure 61 includes a first middle atomic layer 611, a first lower atomic layer 612 and a first upper atomic layer 613 in which the first lower atomic layer 612 and the first upper atomic layer 613 are disposed on lower and upper surfaces of the first middle atomic layer 611 respectively. The second layered atomic structure 62 includes a second middle atomic layer 621, a second lower atomic layer 622 and a second upper atomic layer 623 in which the second lower atomic layer 622 and the second upper atomic layer 623 are disposed on lower and upper surfaces of the second middle atomic layer 621 respectively.

The first middle atomic layer 611 and the second middle atomic layer 621 are 2D planar atomic structures formed of a transition metal selected from the group consisting of titanium (Ti), vanadium (V), chromium (Cr), manganese (Mn), iron (Fe), cobalt (Co), nickel (Ni), copper (Cu), tin (Sn), zinc (Zn), zirconium (Zr), niobium (Nb), molybdenum (Mo), cadmium (Cd), hafnium (Hf), platinum (Pt), tantalum (Ta), tungsten (W), and rhenium (Re); and the lower atomic layer 12 and the upper atomic layer 13 are formed of sulfur, selenium, or tellurium.

In the embodiment, the double-layer artificial 2D material 6 is a 2D crystalline material. The first lower atomic layer 612 and the first upper atomic layer 613 are a 2D planar atomic structure formed of heterogeneous atoms. Atoms of the first layered atomic structure 61 are bound by chemical bonding. The second lower atomic layer 622 and the second upper atomic layer 623 are a 2D planar atomic structure formed of heterogeneous atoms. Atoms of the second layered atomic structure 62 are bound by chemical bonding. The first layered atomic structure 61 and the second layered atomic structure 62 are bound by van der Waals forces.

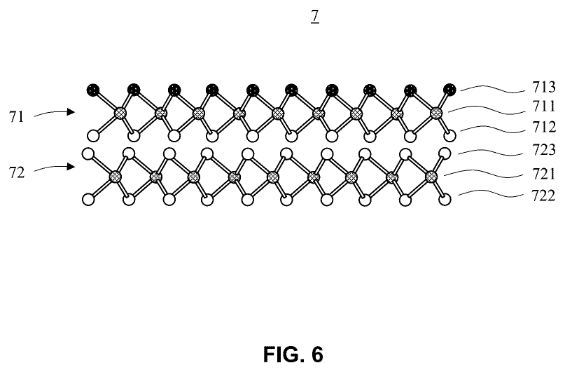

Referring to FIG. 6, an artificial double-layer 2D material 7 in accordance with a sixth preferred embodiment of the invention is shown. The characteristics of the sixth preferred embodiment are substantially the same as that of the fifth preferred embodiment except the following: the artificial double-layer 2D material 7 comprises a first layered atomic structure 71 and a second layered atomic structure 72. The first layered atomic structure 71 includes a first middle atomic layer 711, a first lower atomic layer 712 and a first upper atomic layer 713 in which the first lower atomic layer 712 and the first upper atomic layer 713 are disposed on lower and upper surfaces of the first middle atomic layer 711 respectively. The second layered atomic structure 72 includes a second middle atomic layer 721, a second lower atomic layer 722 and a second upper atomic layer 723 in which the second lower atomic layer 722 and the second upper atomic layer 723 are disposed on lower and upper surfaces of the second middle atomic layer 721 respectively. The first middle atomic layer 711 and the second middle atomic layer 721 are a 2D planar atomic structure formed of a transition metal selected from the group consisting of titanium (Ti), vanadium (V), chromium (Cr), manganese (Mn), iron (Fe), cobalt (Co), nickel (Ni), copper (Cu), tin (Sn), zinc (Zn), zirconium (Zr), niobium (Nb), molybdenum (Mo), cadmium (Cd), hafnium (Hf), platinum (Pt), tantalum (Ta), tungsten (W), and Rhenium (Re). The first lower atomic layer 712, the second lower atomic layer 722 and the second upper atomic layer 723 are formed of sulfur, selenium, or tellurium. The first upper atomic layer 713 is a first metal atomic layer made of metals selected from the group consisting of nickel (Ni), tungsten (W), copper (Cu), titanium (Ti), palladium (Pd), bismuth (Bi), antimony (Sb), and platinum (Pt). In the embodiment, the artificial double-layer 2D material 7 is a 2D crystalline material. The first lower atomic layer 712 and the first upper atomic layer 713 are a 2D planar atomic structure formed of heterogeneous atoms. Atoms of the first middle atomic layer 711 and the first upper atomic layer 713 are bound by metallic bonding. As a result, an artificial 2D alloy material having a first metal-transition metal-sulfur junction structure, i.e., two heterogeneous junctions are formed. The second lower atomic layer 722 and the second upper atomic layer 723 are a 2D planar atomic structure formed of homogeneous atoms. Atoms of the second layered atomic structure 72 are bound by chemical bonding, and the first layered atomic structure 71 and the second layered atomic structure 72 are bound by van der Waals forces.

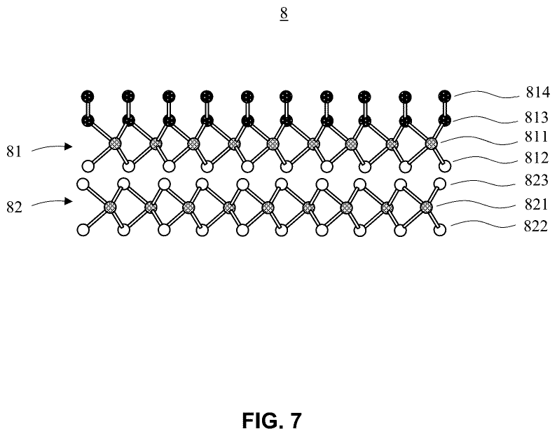

Referring to FIG. 7, an artificial double-layer 2D material 8 in accordance with a seventh preferred embodiment of the invention is shown. The seventh preferred embodiment aims to meet the demands of more 2D material applications and advanced semiconductor manufacturing processes including depositing metal layer. The characteristics of the seventh preferred embodiment are substantially the same as that of the sixth preferred embodiment except the following description. The artificial double-layer 2D material 8 comprises a first layered atomic structure 81 and a second layered atomic structure 82. The first layered atomic structure 81 includes a first middle atomic layer 811, a first lower atomic layer 812, a first upper atomic layer 813 and a first outer atomic layer 814 in which the first lower atomic layer 812 and the first upper atomic layer 813 are disposed on lower and upper surfaces of the first middle atomic layer 811 respectively. The second layered atomic structure 82 includes a second middle atomic layer 821, a second lower atomic layer 822 and a second upper atomic layer 823 in which the first lower atomic layer 822 and the first upper atomic layer 823 are disposed on lower and upper surfaces of the first middle atomic layer 821 respectively. The first middle atomic layer 811 and the second middle atomic layer 821 are a 2D planar atomic structure formed of a transition metal selected from the group consisting of titanium (Ti), vanadium (V), chromium (Cr), manganese (Mn), iron (Fe), cobalt (Co), nickel (Ni), copper (Cu), tin (Sn), zinc (Zn), zirconium (Zr), niobium (Nb), molybdenum (Mo), cadmium (Cd), hafnium (Hf), platinum (Pt), tantalum (Ta), tungsten (W), and Rhenium (Re). The first lower atomic layer 812, the second lower atomic layer 822 and the second upper atomic layer 823 are formed of sulfur, selenium, or tellurium. The first upper atomic layer 813 is a first metal atomic layer made of metals selected from the group consisting of nickel (Ni), tungsten (W), copper (Cu), titanium (Ti), palladium (Pd), bismuth (Bi), antimony (Sb), and platinum (Pt). The first outer atomic layer 814 may be a second metal atomic layer made of metals selected from the group consisting of cobalt (Co), nickel (Ni), tungsten (W), copper (Cu), titanium (Ti), palladium (Pd), bismuth (Bi), antimony (Sb), scandium (Sc), vanadium (V), gold (Au) and platinum (Pt). In the embodiment, the artificial double-layer 2D material 8 is a 2D crystalline material. The first lower atomic layer 812 and the first upper atomic layer 813 are a 2D planar atomic structure formed of heterogeneous atoms. Atoms of the first middle atomic layer 811 and the first upper atomic layer 813 are bound by metallic bonding. As a result, an artificial 2D alloy material having a second metal (or first metal)-transition metal-sulfur junction structure, i.e., two different junctions is formed. The second lower atomic layer 822 and the second upper atomic layer 823 are a 2D planar atomic structure formed of homogeneous atoms. Atoms of the second layered atomic structure 82 are bound by chemical bonding, and the first layered atomic structure 81 and the second layered atomic structure 82 are bound by van der Waals forces.

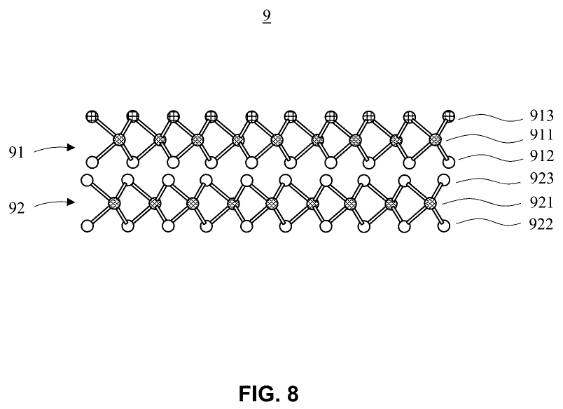

Referring to FIG. 8, an artificial double-layer 2D material 9 in accordance with an eighth preferred embodiment of the invention is shown. The artificial double-layer 2D material 9 comprises a first layered atomic structure 91 and a second layered atomic structure 92. The first layered atomic structure 91 includes a first middle atomic layer 911, a first lower atomic layer 912, a first upper atomic layer 913. The characteristics of the eighth preferred embodiment are substantially the same as that of the fifth, sixth, and seventh preferred embodiment except the following: the upper atomic layer 913 is formed of oxygen (O), phosphor (P), nitrogen (N), chlorine (Cl), carbon (C), or fluorine (F). In the embodiment, the artificial double-layer 2D material is a 2D compound material. Taking oxygen atoms as an example, an artificial 2D compound material having an oxygen-transition metal-sulfur junction structure, i.e., two heterogeneous junctions is formed.

As described above, an artificial 2D material having two a plurality of heterogeneous junctions is formed. It is understood that a method of manufacturing the artificial 2D material having two heterogeneous or homogenous junctions can be implemented depending on applications. In the above embodiments, the artificial 2D material has three or four atomic layers. It is understood that the artificial 2D material of the invention is not limited to have three or four layers. The method of the invention can manufacture an artificial 2D material having more atomic layers depending on applications.

Conventionally, semiconductor material field employs various synthesis technologies to change size and phase, eliminate deficiencies, introduce impurities (“doping”) into the crystal structure, and use high entropy alloys so that semiconductor material can have more advantageous features and ubiquitous properties which are useful in energy, optoelectronics, etc. However, conventional technologies cannot precisely control synthesis in atoms. Regarding synthesis of semiconductor material, it is understood that removal of atomic layers of a 2D material may generate unsaturated compounds which will be oxidized when exposed to the atmosphere in the process of depositing metal. Further, precursors of non-metal atomic bonds and electrical measurements are adversely affected by moisture. Therefore, atomic scale bonding and control are required in vacuum or a specific environment of, for example inert gas.

The invention provides an atomic scale synthesis platform for semiconductor material. The synthesis platform is precisely controlled to produce a novel material which is very useful for material science including development of new materials.

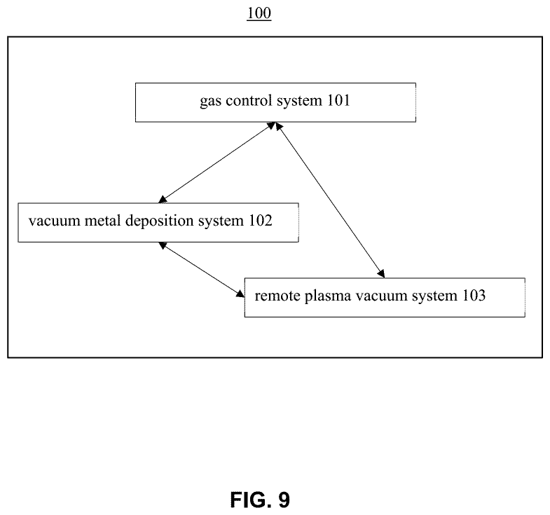

Referring to FIG. 9, it is a block diagram of a synthesis platform 100 for the artificial 2D material/the artificial double-layer 2D material of the invention. The synthesis platform 100 includes a gas control system 101, an ultra-high vacuumed metal deposition system 102 and a remote plasma vacuum system 103 connected together. The artificial 2D material can be transferred among the three systems to achieve the purposes of removing atomic layers of the artificial 2D material and binding heterogeneous atoms. The ultra-high vacuumed metal deposition system 102 includes a metal deposition system such as thermal evaporation deposition system, electron beam evaporation system, or plasma sputtering system. The ultra-high vacuumed metal deposition system 102 can form a 2D metal atomic layer deposition. Further, the ultra-high vacuumed metal deposition system 102 has a stage for supporting the artificial 2D material, the stage is a cooling platform kept at a temperature less than −195.79° C. Preferably, the temperature is between room temperature and −269° C. The purpose of keeping the cooling platform is to prevent the energy of metal atoms evaporated by the thermal evaporation deposition system from transferring to surfaces of a 2D material. Otherwise, atomic defects may be generated on the 2D material. In short, the cooling platform aims to decrease probability of such damage. Moreover, temperature of the cooling platform can be increased to, for example a maximum of 250° C. and a rotational speed of 2 to 40 rpm. The ultra-high vacuumed metal deposition system 102 can deposit all required metallic films which can be of alloy or a single metal selected from the group consisting of titanium (Ti), vanadium (V), chromium (Cr), manganese (Mn), iron (Fe), cobalt (Co), nickel (Ni), copper (Cu), tin (Sn), zinc (Zn), zirconium (Zr), niobium (Nb), molybdenum (Mo), cadmium (Cd), gold (Au), platinum (Pt), hafnium (Hf), tantalum (Ta), bismuth (Bi), tungsten (W), rhenium (Re) and antimony (Sb). The ultra-high vacuumed metal deposition system 102 operates at an atmospheric pressure of 10⁻²-10⁻¹⁰ Torr (i.e., high quality vacuum). Therefore, metal oxidation is avoided and the metal deposition rate is between 0.01 Å /second and 1 Å /second.

The remote plasma vacuum system 103 is capable of introducing a number of plasmas including hydrogen (H), oxygen (O) and nitrogen (N)-based radicals for reaction. The remote plasma vacuum system 130 includes a remote chamber and a reaction chamber (both no shown). Precursor is ionized in the remote chamber prior to entering the reaction chamber having required samples (e.g., MoS₂ or other 2D materials) stored therein. The reaction chamber is spaced apart from the remote chamber and has a shield for the protection of the artificial 2D material impinged by plasmas. The remote plasma vacuum system 103 is capable of performing annealing at various temperature. In detail, after plasma has been used, an annealing is performed by the remote plasma vacuum system 103 (or the remote plasma vacuum system 103 increases temperature to 100-1000° C.) to repair defected lattices.

The plasma treatment disclosed in the method of manufacturing the artificial double-layer 2D material in this invention requires to be completed under high vacuum conditions. This is because, during the removal of S, Mo is exposed and prone to oxidation in the air. Moreover, prolonged plasma bombardment can directly damage the MoS₂ structure. Therefore, double-layer MoS₂ is used to improve this issue. The upper layer of MoS₂ is implemented as a protective layer to reduce defects caused by plasma bombardment and metal deposition. Subsequently, only low-damage plasma is used for bombardment. After plasma treatment, depositing Ti/Au metal can effectively enhance electrical properties. Compared to a monolayer that has not undergone plasma treatment, the Iₒₙ of double-layer MoS₂ increases from the 9.65×10⁻⁴ μA/μm to 2.26×10⁻² μA/μm, and the electron mobility is improved by up to 21 times. Furthermore, after low-damage plasma treatment for 3 minutes, Iₒₙ increases to 4.47×10⁻¹ μA/μm, and the electron mobility is improved by up to 50 times. Additionally, hydrogen plasma treatment caused a notable N-type doping effect on Vth.

The gas control system 101 includes a chamber kept at a constant pressure and filled with inert gas (e.g., N₂, Ar, etc.). Within the chamber, there are also provided with a plurality of devices for manufacturing processes. The devices include heater, ovens, containers for chemical solution, etc. The precursor can be processed in the chamber. In detail, after an upper atomic layer of a 2D material has been removed, the gas control system 101 executes chemical processes including immerging, spraying and scrubbing to improve chemical properties of the 2D material. As such, the precursor can be adhered to the 2D material. The heaters or ovens are used to remove unnecessary solvent or atoms. As a result, metal atoms are bound or atoms of a compound of C, N, O and F are bound.

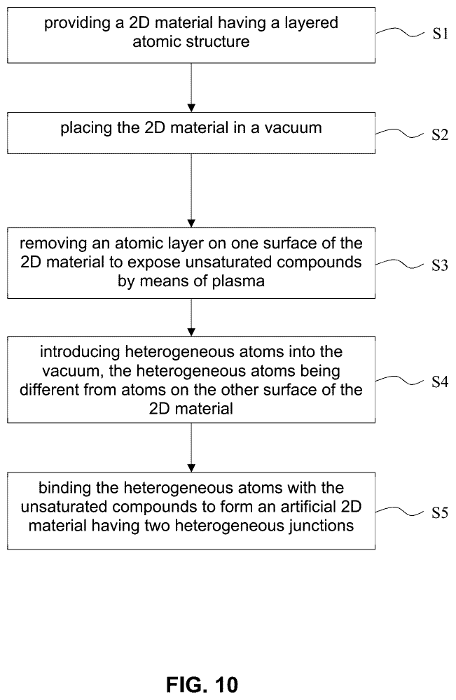

Referring to FIG. 10 it is a flow chart of a method of manufacturing an artificial 2D material according to the invention using the synthesis platform 100, the artificial 2D material being that described in the first, second, third and fourth preferred embodiments. The method comprises the steps of S1 providing a 2D material having a layered atomic structure wherein the 2D material is selected from the group consisting of boron nitride (h-BN), silicone, germanene, stanene, phosphorene, and one of transition metal dichalcogenides (TMDs) including molybdenum disulfide (MoS₂), tungsten disulfide (WS₂), tungsten diselenide (WSe₂), and indium (II) selenide (InSe); S2 placing the 2D material in an vacuum; S3 removing an atomic layer on one surface of the 2D material to expose unsaturated compounds by means of plasma (e.g., argon plasma or hydrogen plasma); S4 introducing heterogeneous atoms into the vacuum wherein the heterogeneous atoms are different from atoms on the other surface of the 2D material; and S5 binding the heterogeneous atoms with the unsaturated compounds to form an artificial 2D material having two heterogeneous junctions.

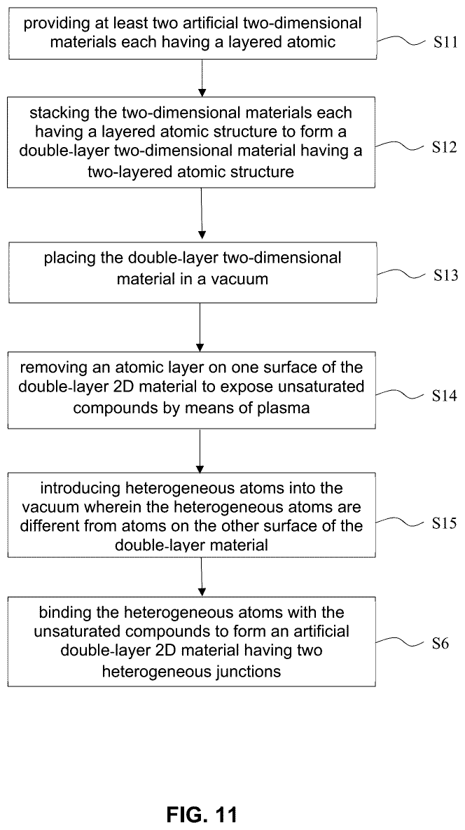

Referring to FIG. 11 it is a flow chart of a method of manufacturing an artificial double-layer 2D material according to the invention using the synthesis platform 100, the artificial double-layer 2D material being that described in the fifth, sixth, seventh and eighth preferred embodiments. The method comprises the steps of S11 providing at least two artificial 2D materials each having a layered atomic structure wherein the 2D material is selected from the group consisting of boron nitride (h-BN), silicone, germanene, stanene, phosphorene, and one of transition metal dichalcogenides (TMDs) including molybdenum disulfide (MoS₂), tungsten disulfide (WS₂), tungsten diselenide (WSe₂), and indium (II) selenide (InSe); S12 stacking the 2D materials each having the layered atomic structure to form a double-layer 2D material having a two-layered atomic structure; S13 placing the double-layer 2D material in a vacuum; S14 removing an atomic layer on one surface of the double-layer 2D material to expose unsaturated compounds by means of plasma (e.g., argon plasma or hydrogen plasma); S15 introducing heterogeneous atoms into the vacuum wherein the heterogeneous atoms are different from atoms on the other surface of the double-layer material; and S16 binding the heterogeneous atoms with the unsaturated compounds to form an artificial double-layer 2D material having two heterogeneous junctions.

Referring to FIGS. 10 and 11, a description of combining the synthesis platform 100 with the method of manufacturing an artificial 2D material/an artificial double-layer 2D material according to the invention is as below. In the embodiment, a 2D transition metal dichalcogenide is used to manufacture a 2D alloy. It is understood that it is possible to manufacture an artificial 2D material having two heterogeneous junctions by means of a 2D material having a different layered atomic structure in other embodiments. In the embodiment, the method comprises the steps of providing a 2D-layered transition metal dichalcogenide (2D TMD) having a layered atomic structure; placing the 2D TMD in an vacuumed atmosphere generated by the remote plasma vacuum system 103; removing an S or Se atomic layer on one surface of the 2D TMD to expose unsaturated compounds by means of hydrogen plasma wherein power is 20-200 W, hydrogen or a mixture thereof flows at a rate of 5-30 sccm, and a pressure is 5-800 mTorr; conveying the 2D TMD to the ultra-high vacuumed metal deposition system 102; introducing heterogeneous atoms into the vacuum wherein the heterogeneous atoms are different from atoms on the other surface of the transition metal layer; and binding the heterogeneous atoms with the unsaturated compounds to form an artificial 2D material/an artificial double-layer 2D material having two heterogeneous junctions. It is understood that above method is exemplary example and is not to limit the scope of the invention. The 2D material is configured to transfer among the three systems to achieve the purposes of atomic layer removal and binding the heterogeneous atoms with the unsaturated compounds. It is also understood that parameters are different in different materials and different manufacturing processes.

The step of removing atomic layers of the method of manufacturing an artificial 2D material/an artificial double-layer 2D material of the invention can be implemented by means of argon plasma or hydrogen plasma.

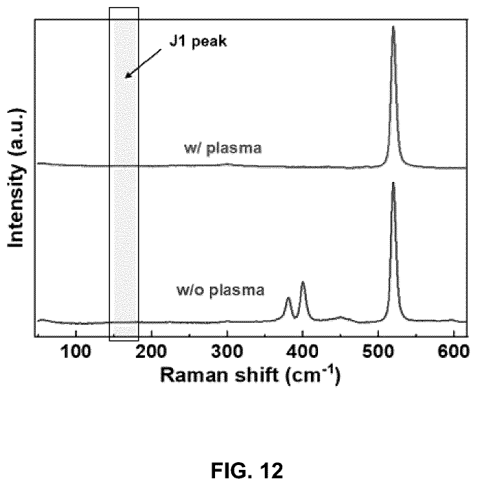

Referring to FIG. 12, it plots Raman shift versus intensity for the artificial 2D material/the artificial double-layer 2D material using hydrogen plasma and not using hydrogen plasma according to the invention in which a Raman spectrum is used to prove junctions of the monolayer have been changed to the desired heterogeneous junctions due to chemical bonding. As shown, there are MoS₂ peaks in the range of 350 to 450 Raman shifts when hydrogen plasma is not used. The peaks are decreased or disappeared in other Raman shifts due to chemical properties changes at the junctions. This proves that the homogeneous junctions of MoS₂ no more exist after hydrogen plasma has been used. Instead, Mo—Ti junction of MoS₂ is formed. As a result, Raman vibration mode is changed. Further, it proves that improvements of junction of source and drain of FET can be obtained other than by etching or removing impurities.

As shown in FIG. 12 specifically, hydrogen plasma is used to remove an atomic layer on one surface of the 2D material. After the removal, it is found that in the Raman spectrum there is no J1 peak which is used to determine whether there is a phase change in MoS₂. If yes, it means the phase has changed to 1T phase. MoS₂ has 2H and 1T phases in which 2H phase is semiconductor based and 1T is metallic. The peak is used to determine whether phase of MoS₂ has changed to 1T phase. Further, it proves that after the processing, the conventional argon plasma leads to change of 2H to 1T. In brief, using hydrogen plasma to in the manufacturing of the artificial 2D material/the artificial double-layer 2D material of the invention can produce an artificial 2D material/the artificial double-layer 2D material having semiconductor properties different from that produced by the conventional manufacturing process. Moreover, the 1T phase of MoS₂ is not a stable phase; it easily changes back to the 2H phase at low temperatures, which is unfavorable for subsequent practical applications.

Moreover, it is found that contact resistance of source/drain of FET is greatly decreased in a metal contact by using argon plasma to change phase to 1T phase. This is because 1T phase is metallic. It should be understood that this structure is S atoms-Mo atoms-S atoms and is not related to the invention which involves removing a layer of S atoms from a monolayer using hydrogen plasma. Further, the bond of Mo atoms and S atoms is broken. It is possible to selectively remove S atoms from the upper atomic layer to obtain an atomic structure of —Mo—S. Also, the junction of Mo and S atoms of the lower layer is not damaged. The non-destruction technique of the invention is critical and contributes the metal contact of the interface. It can decrease contact resistance and improve semiconductor's performance by not causing destruction or phase change.

In the third embodiment of the invention, a method of manufacturing an artificial 2D material comprises she steps of providing transition metal MoS₂; removing an atomic layer of S atoms on one surface of the 2D material to expose unsaturated compounds of —Mo—S by means of hydrogen plasma; placing the 2D material having the unsaturated compounds of —Mo—S in the gas control system 101; immersing a precursor (e.g., PtCl₂) in the gas control system 101 so that the unsaturated compounds of —Mo—S may bind Pt atoms; drying contents in the gas control system 101; conveying the dried content in the gas control system 101 to the remote plasma vacuum system 103; annealing the content in the remote plasma vacuum system 103 at a temperature of 50-600° C. using H₂ (or Ar); removing remaining Cl so that defects can be eliminated to manufacture a crystalline 2D material (Pt—Mo—S). In the third embodiment, the produced 2D material is further conveyed to the ultra-high vacuumed metal deposition system 102 to evaporating other metal atoms such as Co/Pt—Mo—S and Cu/Pt—Mo—S atoms. It is understood that above principles can be applied to cause Cu/W—Mo—S and W/Cu—Mo—S atoms to deposit a metal layer in contact. The 2D material is capable of transferring among three systems to achieve above purposes of removing atomic layers of the artificial 2D material and binding heterogeneous atoms so as to apply to both different materials and different manufacturing processes which require different parameters. It is understood that above description is exemplary and the invention is not limited by it. Any 2D material including alloy material can be used to manufacture an artificial 2D material having heterogeneous junctions and they are within the scope of the invention.

In the third embodiment of the invention, a 2D layered material is provided to manufacture MoOx, HfO₂ or Ti_{0.87}O₂ which is adapted to apply to gate insulating layer. Likewise, after an atomic layer of S atoms has been removed using hydrogen plasma, oxygen plasma (e.g., monolayer ALO) can be used to oxidize the 2D layered material to form an O—Mo—S structure which may facilitate ALD to form a gate insulating layer. Alternatively, after the atomic layer of S atoms has been removed, the 2D layered material can be transferred to a next station for evaporating Ti. Next, the 2D material is transferred to a next station to subject to oxygen plasma and annealing. As a result, TiOx is deposited on the surface of —Mo—S to form an insulator TiOx—Mo—S. In another aspect, it is possible to synthesize a HfS₂ structure on the surface of the 2D material, i.e., passing a precursor (Hf:TDMAH+S) through the remote plasma vacuum system 103, use O₂ to remove S atoms, and finally produce HfO₂/MoS₂.

In above method of manufacturing the artificial 2D material, the gas control system 101, the ultra-high vacuumed metal deposition system 102 and the remote plasma vacuum system 103 are interconnected. Each step such as removing an atomic layer or binding atoms can return to the gas control system 101 for check. A scanning probe microscope (SPM) is used to investigate the mechanical properties of the surface of the 2D material. Alternatively, Raman spectrometer or PL spectrometer is used to analyze differences between before and after the execution of atomic layer removal and bound chemical bonds. Further, a real time measurement of positive or negative of the film is performed in order to determine whether a metal layer or an oxidation layer is formed or not. Furthermore, an optical emission spectroscopy is used to monitor whether a reaction of atomic layer epitaxy/atomic layer deposition (ALE/ALD) is finished or not. Times of beginning and ending of the reaction can be obtained by observing S time curve of ALE S spectrum. This can precisely control the reaction and does not damage the 2D material. Finally, an annular dark-field scanning transmission electron microscopy (ADF-STEM) is used to analyze lattices and compositions at the junctions.

Regarding applications in electronic components, the 2D material is, for example for the manufacture of semiconductor devices. Thus, the 2D material is required to have acceptable energy gaps, high carrier mobility, high on-current, low energy consumption, high integration, and high reliability. Thus, there are many problems to be solved prior to mass production. These problems include controllability of large area synthesis, wafer level transfer, contact resistance, and reliability analysis of components. Particularly, the 2D materials are required to be compatible with current semiconductor manufacturing processes including extreme ultraviolet (EUV) radiation used in photolithography, patterns, metallic processes, and deposition and annealing of high-K materials. Factors including EUV photons used in photolithography capable of penetrating photoresist to damage the 2D material, and impact and reliability of electronic components made of conventional 2D material should be taken into consideration in the development of new 2D materials.

The invention provides an artificial 2D material having two heterogeneous junctions for electronic components. Further, the invention provides a method of manufacturing the artificial 2D material having two heterogeneous junctions in room temperature using remote plasma. The method is compatible with current semiconductor manufacturing processes. Thus, the method of the invention may use both photoresist and EUV radiation used in photolithography to form an artificial 2D material and both atomic layer removal and binding atoms can be performed on the artificial 2D material to obtain desired purposes.

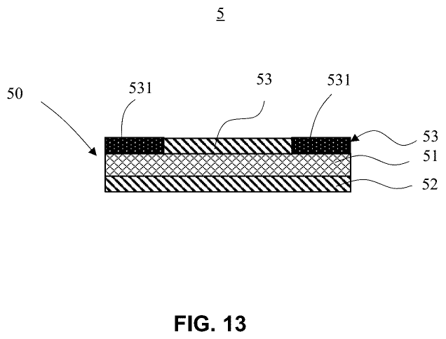

Referring to FIG. 13, it is a longitudinal sectional view of an artificial 2D material 5 showing a monolayer having a plurality of heterogeneous junctions according to a ninth preferred embodiment of the invention. The artificial 2D material 5 is manufactured according to the method illustrated in FIG. 10 and is implemented as a layer having a plurality of heterogeneous zones as detailed below. The artificial 2D material 5 includes a middle atomic layer 51, a lower atomic layer 52 and an upper atomic layer 53. In the embodiment, the upper atomic layer 53 is a heterogeneous atomic layer.

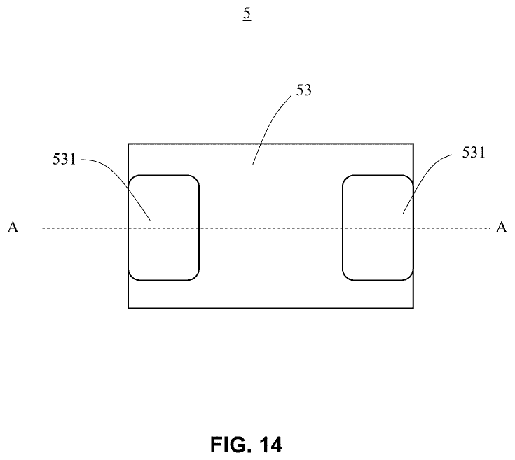

Referring to FIG. 14 in conjunction with FIG. 13 in which FIG. 14 is a top plan view of the artificial 2D material 5. The upper atomic layer 53 includes two spaced heterogeneous zones 531 each implemented as a metal atomic layer or a layer formed of oxide and other chemical compounds (e.g., nitride). A method of manufacturing the artificial 2D material 5 having a plurality of heterogeneous junctions comprises the steps of providing a 2D material having a layered structure. In the embodiment, the 2D material having the layered structure is a 2D TMD (e.g., MoS₂). MoS₂ includes a middle atomic layer 51, a lower atomic layer 52 and an upper atomic layer 53 in which the middle atomic layer 51 is made of, but not limited to Mo; the upper atomic layer 53 is made of, but not limited to sulfur(S); and the lower atomic layer 52 and the upper atomic layer 33 are disposed on lower and upper surfaces of the middle atomic layer 51 respectively. The method of the invention removes portions of the upper atomic layer 33 using hydrogen plasma, and binding heterogeneous atoms by chemical bonding to form a monolayer having a plurality of heterogeneous zones. The monolayer includes the upper atomic layer 53 and the heterogeneous zones 531.

As shown in FIG. 14 specifically, it is a top plan view of the artificial 2D material 5 and as shown in FIG. 13 specifically, it is a sectional view taken along line A-A of FIG. 9. It is understood that an artificial 2D material having heterogeneous zones is not limited to that shown in FIG. 13; and further, an artificial 2D material is not limited to have two heterogeneous zones 531 as shown in FIG. 13 or FIG. 14. An artificial 2D material having heterogeneous zones can be made depending on different manufacturing steps and different electronic components. The embodiment is only exemplary. An ordinary person skilled in the art can manufacture an artificial 2D material including a monolayer having a plurality of heterogeneous junctions using the method of the invention. The produced artificial 2D material can be used to manufacture rectifiers, integrated circuits and semiconductor devices including FETs.

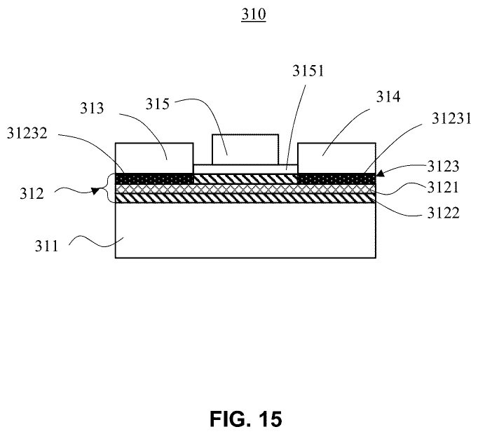

Referring to FIG. 15, it is a schematic longitudinal sectional view of an electronic component (e.g., FET) 310 according to a first configuration of the invention, the electronic component 310 incorporating the artificial 2D material (MoS₂) of the invention. It is noted that the artificial 2D material can be a different chemical compound in other embodiments. In the embodiment, the electronic component 310 includes a substrate 311, an artificial 2D material layer 312, a source 312, a drain 314 and a gate 315. The artificial 2D material layer 312 includes a middle atomic layer 3121, a lower atomic layer 3122 below the middle atomic layer 3121, and an upper atomic layer 3123 on the middle atomic layer 3121. The upper atomic layer 3123 is heterogeneous and includes a first heterogeneous zone 31231 and a second heterogeneous zone 31232 spaced from the first heterogeneous zone 31231. In the embodiment, the first and second heterogeneous zones 31231, 31232 each implemented as a metal atomic layer. The source 313 is provided on the second heterogeneous zone 31232 and the drain 314 is provided on the first heterogeneous zone 31231 respectively. Each of the source 313 and the drain 314 are metallic electrodes. Thus, the source 313 is electrically connected to the metal atomic layer of the second heterogeneous zone 31232 by means of metallic bonding and the drain 314 is electrically connected to the metal atomic layer of the first heterogeneous zone 31231 by means of metallic bonding respectively.

A method of manufacturing the electronic component 310 of FIG. 15 comprises the steps of depositing an insulating layer on the substrate 311 using chemical vapor deposition (CVD) or atomic layer deposition (ALD) wherein the insulating layer includes SiO₂, Si₂N₃, Al₂O₃, Hf₂O₃ and BN or CaF; form an artificial 2D material layer 312 as a semiconductor channel material, using first photolithography to create minutely patterned thin films of suitable materials over the artificial 2D material layer 312; using etching (e.g., plasma etching) to chemically remove layers from the surface of artificial 2D material layer 312; using second photolithography to create minutely patterned thin films (e.g., the source 313 and the drain 314) of suitable materials over the artificial 2D material layer 312; using photoresist to form a patterned coating on the surface of the artificial 2D material layer 312 wherein the second heterogeneous zone 31232 under the source 313 and the first heterogeneous zone 31231 under the drain 314 are exposed respectively; using hydrogen plasma to remove atomic layers so as to form an Mo—S structure; metalizing wherein electronic beam evaporation is performed on the above metals so as to deposit a metal atomic layer on each of the first heterogeneous zone 31231 and the second heterogeneous zone 31232, thereby forming an M—Mo—S 2D alloy material layer thereon; forming the source 313 and the drain 314 on the n M—Mo—S 2D alloy material layer; forming a gate insulating layer 3151 including SiO₂, Al₂O₃, Hf₂O₃, and BN or CaF on the artificial 2D material layer 312; and finally using photolithography and deposition to form the gate 315 on the gate insulating layer 3151, thereby producing the electronic component 310.

Moreover, the same method steps can be arranged different in other embodiments as described in detailed below.

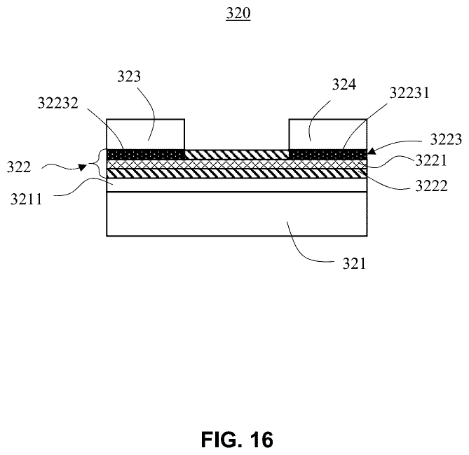

Referring to FIG. 16, it is a schematic longitudinal sectional view of an electronic component 320 according to a second configuration of the invention, the electronic component 320 incorporating the artificial 2D material of the invention. The electronic component 320 is implemented as a back-gated FET in which a highly doped substrate 321 (e.g., P⁺⁺ or N⁺⁺Si) is used as a fin. The method of manufacturing the electronic component 320 comprises the steps of depositing a gate insulating layer 3211 (e.g., Al₂O₃, SiO₂, nitride, or fluoride (e.g., CaF)); forming the artificial 2D material layer 322 including a middle atomic layer 3121, a lower atomic layer 3222 below the middle atomic layer 3221, and an upper atomic layer 3223 on the middle atomic layer 3221. The upper atomic layer 3223 is heterogeneous and includes a first heterogeneous zone 32231 and a second heterogeneous zone 32232 spaced from the first heterogeneous zone 32231. In the embodiment, the first and second heterogeneous zones 32231, 32232 each implemented as a metal atomic layer. The source 323 is provided on the second heterogeneous zone 32232 and the drain 324 is provided on the first heterogeneous zone 32231 respectively. Each of the source 323 and the drain 324 are metallic electrodes. Thus, the source 323 is electrically connected to the metal atomic layer of the second heterogeneous zone 32232 by means of metallic bonding and the drain 324 is electrically connected to the metal atomic layer of the first heterogeneous zone 32231 by means of metallic bonding respectively. The method of manufacturing the electronic component 320 further comprises the steps of using photolithography and deposition to form the channel on the gate insulating layer 3211; finally using hydrogen plasma to remove the upper metal layers, materials using ALE and then conjugation with metal both based on the source 323 and the drain 324, thereby producing the electronic component 320.

Above electronic components further comprise FinFET, gate-all-around FET (GAAFET), stacked nanosheet FET, and multi-bridge channel FET (MBCFET). Above characteristics are related to selectively remove atomic layers from the source and the drain to decrease their contact resistance. Regarding heterogeneous junctions, above method can be used to synthesize a gate insulating layer as a structure of next generational as GAAFET. GAAFETs can inhibit leakage current and have better channel control. But the thin channel of GAAFET limits current density. Also, a vertical multi-channel limits height and causes interference with internal connection layers. Further, parasite capacitance adversely affects switching rate. The main bottleneck is that the manufacturing steps of the nanoscale GAAFET are more complicated and in turn it greatly increases the manufacturing cost and lowers yield. Thus, a stacked nanosheet FET is considered to be the optimum scheme for solve above problems. However, regarding the manufacturing of the stacked nanosheet FET, a Si/SiGe super lattice is used to selectively remove SiGe from the stacked nanosheet FET to obtain a suspended nanoscale element of Si. Next, ALD is performed to deposit a dielectric layer and a gate metal layer. But there is challenge to conformal coating of ALD and is different from the steps of the conventional CMOS process. Further, both nanosheet and GAAFET require an atomic layer deposition to fill gaps in the suspended lower layer. However, it greatly increases difficulties of manufacturing the semiconductor devices. Further, there is no disclosure about using 2D semiconductor to verify the structure of the semiconductor devices.

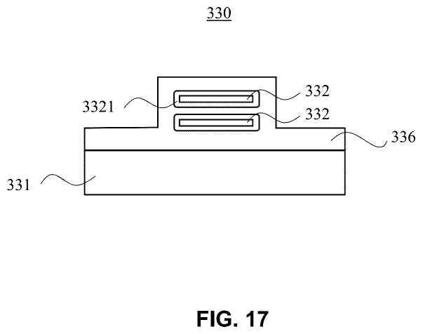

Referring to FIG. 17, it is a schematic longitudinal sectional view of an electronic component 330 according to a third configuration of the invention, the electronic component 330 incorporating the artificial 2D material of the invention. The electronic component 330 may be an electron encircling gate field-effect transistor. The electronic component 330 includes a substrate 331, a gate 336 provided on the substrate 331, a plurality of (two are shown) spaced, staked artificial 2D material layers 332 in the gate 336, and a plurality of (two are shown) gate insulating layers (e.g., oxide layers or layers made of an insulator material such as nitride or fluoride) 3321 in the gate 336 and each wrapped around the artificial 2D material layer 332. In the third configuration, a TMD is staked in MoS₂/oxide/MoS₂/oxide. Next, reactive-ion etching (RIE) is used to define source/drain and contact and remove deposited materials to form the defined pattern with MoS₂ nanosheets exposed. It is noted that in above method the insulating layer in 2D nanosheet is required to remove. Finally, use ALD to fill drive-in metal precursor in the metal gate 336 which wraps around the 2D channels. It is understood that various heterostructures including 2D semiconductor and metal junctions, insulator oxides, and 2D semiconductor devices (e.g., PRAM, rectifiers, etc.) by taking advantage of above two principles.

In the artificial 2D oxide having heterogeneous junctions, an optimum k value of 2D-TiO₂ is about equal to 125 and it is appropriate for semiconductor gate dielectric layer. In other embodiments, the gate insulating layer is a 2D layered oxide such as MoOx, HfO₂ or Ti_{0.87}O₂. By utilizing the same principle, the method comprises the following steps: After an atomic layer of S atoms has been removed using hydrogen plasma in the remote plasma vacuum system, oxygen plasma (e.g., monolayer ALO) can be used to oxidize the 2D layered material to form an O—Mo—S structure which may facilitate ALD to form a gate insulating layer. Alternatively, after the atomic layer of S atoms has been removed, the 2D layered material can be transferred to a next station for evaporating Ti. Next, the 2D material is transferred to the remote plasma vacuum system to subject to oxygen plasma and annealing. As a result, TiOx is deposited on the surface of —Mo—S to form an insulator TiOx—Mo—S. In another aspect, it is possible to synthesize a HfS₂ structure on the surface of the 2D material, i.e., passing a precursor (Hf:TDMAH+S) through the remote plasma vacuum system, use O₂ to remove S atoms, and finally produce HfO₂/MoS₂. Moreover, the remote plasma vacuum system may use hydrogen plasma to remove S atoms from the surfaces of synthesized nitride (or other 2D chemical compound) and in turn transfer the synthesized nitride (or other 2D chemical compound) to the gas control system to be processed by inert gas under a constant pressure. Also, the solution precursor is used to bind the synthesized nitride (or other 2D chemical compound) with chemical bonding. This process is a wet process and can adhere precursors including N, C and p atoms to the synthesized nitride (or other 2D chemical compound) by immersing. The manufacturing of the 2D insulating layer can be applied to the manufacturing of insulating layers of the above electronic components such as the gate insulating layer 3151 of FIG. 10, the gate insulating layer 3221 of FIG. 11 and the gate insulating layer 3321 of FIG. 12.

It is noted that the synthesis can be achieved using the interconnected systems of FIG. 9. Load lock chambers and vacuum valves are used by the systems for transferring materials among them in a closed environment. The remote plasma vacuum system includes a chamber having a low damage to remote plasma which is one of H, Ar, O and N plasmas by switching. The systems thus carry out processes such as ALE and atomic layer oxidation (ALO). The gas control system is implemented as chamber containing inert gas under a constant pressure so that a number of precursor processes including wet type adhering and binding with chemical bonding. The electronic beam evaporation system is implemented as an ultra-high vacuumed chamber and is capable of precisely depositing different metal atoms.

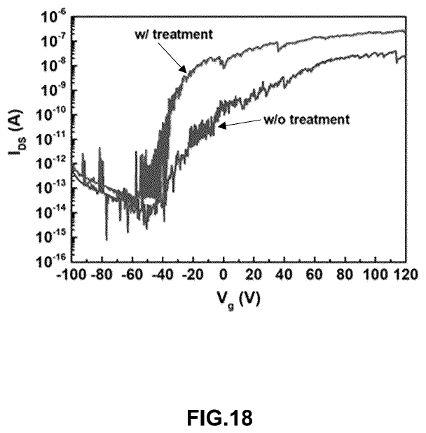

Referring to FIG. 18, it plots V_{G}(V) versus I_{DS}(A) for an electronic component formed of artificial 2D material of the first preferred embodiment of the invention with or without treatment as comparison. Source and drain contact are processed at the same channel material. It is found that the electronic component's performance in electronic properties is greatly increased. It is concluded that a metallized 2D material has improved carrier injection conjunctions and greatly increased performance.

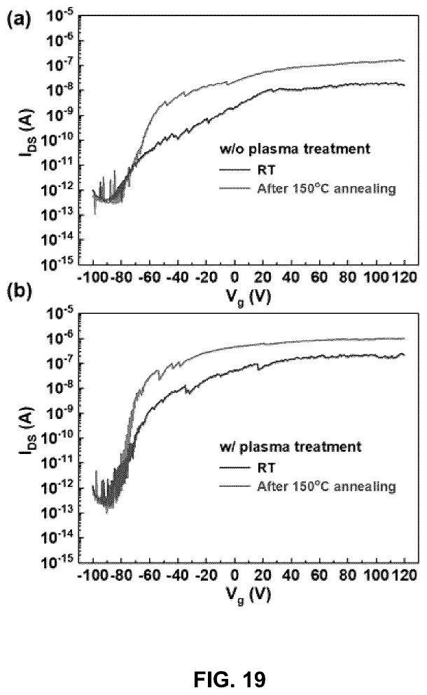

Referring to FIG. 19, in part (a) it plots V_{G}(V) versus I_{DS}(A) for an electronic component formed of artificial 2D material of the first preferred embodiment of the invention without plasma treatment; and in part (b) it plots V_{G}(V) versus I_{DS}(A) for an electronic component formed of artificial 2D material of the first preferred embodiment of the invention with plasma treatment. The electronic component is implemented as Ti—Mo—S semiconductor device. As shown in part (a), the Ti—Mo—S semiconductor device has not been treated by plasma and has been processed by 150° C. annealing, and has decreased contact resistance. But it is not reliable. Further, other electrical properties including low on-off ratio, low carrier mobility and high subthreshold swing are not desired. As a comparison, as shown in part (b), the Ti—Mo—S semiconductor device has been treated by plasma and has been processed by 150° C. annealing, and has decreased contact resistance. Also, it is reliable. Further, other electrical properties including high on-off ratio, high carrier mobility and low subthreshold swing are desired. It is noted that the annealing temperature is between 50-900° C. and preferably, between 50-300° C.

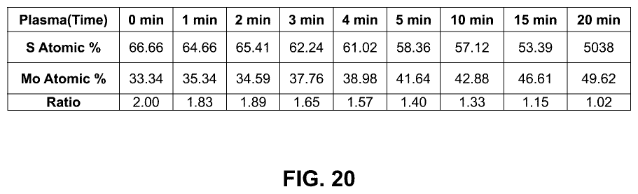

XPS is used to measure the ratios and orbital changes of Mo and S to analyze the changes in the proportion of the MoS₂. The S 2p^{3/2} and 2p^{1/2} orbitals typically show peaks at 162.0 eV and 163.2 eV, respectively, with an area ratio of 2:1. However, after 10 minutes, the energy difference between these peaks increases significantly from 1.2 eV to 2.1 eV. After 15 and 20 minutes, the area ratio of the orbitals decreases from 2:1 to 1.11:1 and 1.26:1, respectively. The intensity of the S 2s peak at 226.3 eV also gradually decreases with prolonged plasma treatment. For the Mo orbitals, the 3d^{5/2} and 3d^{3/2} peaks are observed at 229.1 eV and 232.3 eV, respectively, with an area ratio of 3:2. After hydrogen plasma treatment, this ratio gradually decreases, reaching 1:1.23 and 1:1.32 after 15 and 20 minutes, respectively. Additionally, the Mo⁶⁺ peak shows a significant increase in intensity at 235.0 eV after plasma treatment, indicating an increasing trend in intensity. Referring to FIG. 20, FIG. 20 shows the molybdenum-to-sulfur ratio of the artificial double-layer 2D material treated with hydrogen plasma at different times according to the present invention, wherein the S/Mo ratio was calculated based on X-ray photoelectron spectroscopy (XPS) measurements. The ratio changes reveal a significant decrease in the S/Mo ratio with prolonged plasma treatment. After 20 minutes of treatment, the ratio drops to 1.02. Therefore, XPS analysis clearly prove that this method can effectively remove the upper layer of sulfur from MoS₂.

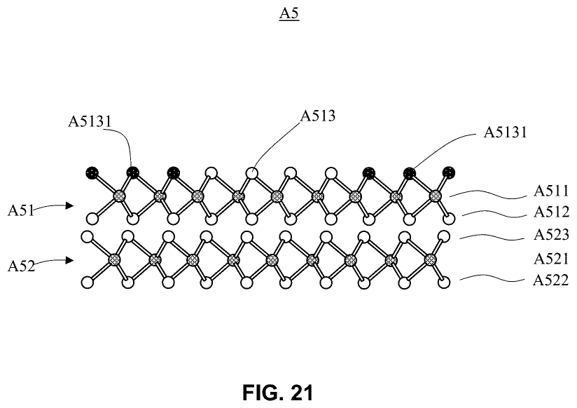

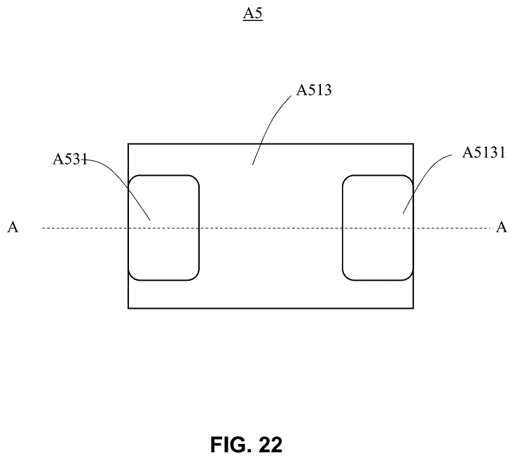

Referring to FIG. 21. a plurality of heterogeneous zones as detailed below. The artificial double-layer 2D material A5 includes a first middle atomic layer A511, a first lower atomic layer A512 and a first upper atomic layer A513, a second middle atomic layer A521, a second lower atomic layer A522 and a second upper atomic layer A523. In the embodiment, the first upper atomic layer A513 is a heterogeneous atomic layer. Referring to FIG. 22 in conjunction with FIG. 21, FIG. 22 is a top plan view of FIG. 21. The first upper atomic layer A513 includes two spaced heterogeneous zones A5131 each implemented as a metal atomic layer or a layer formed of oxide and other chemical compounds (e.g., nitride). A method of manufacturing the artificial double-layer 2D material 5 having a plurality of heterogeneous junctions comprises providing a double-layer 2D material having a first layered atomic structure and a second layered atomic structure. In the embodiment, the first layered structure is a 2D TMD (e.g., MoS₂). MoS₂ includes a first middle atomic layer A511, a first lower atomic layer A512 and a first upper atomic layer A513 in which the first middle atomic layer A511 is made of, but not limited to Mo; the first lower atomic layer A512 and the first upper atomic layer A513 are made of, but not limited to sulfur (S); and the first lower atomic layer A512 and the first upper atomic layer A513 are disposed on lower and upper surfaces of the first middle atomic layer A511 respectively. The second layered structure is also a 2D TMD (e.g., MoS₂). MoS₂ includes a second middle atomic layer A521, a second lower atomic layer A522 and a second upper atomic layer A523 in which the second middle atomic layer A521 is made of, but not limited to Mo; the second lower atomic layer A522 and the second upper atomic layer A523 are made of, but not limited to sulfur (S); and the second lower atomic layer A522 and the second upper atomic layer A523 are disposed on lower and upper surfaces of the second middle atomic layer A521 respectively. The method of the invention removes portions of the first upper atomic layer A513 using hydrogen plasma, and binding heterogeneous atoms by chemical bonding to form a layer having a plurality of heterogeneous zones. The layer having a plurality of heterogeneous zones includes the first upper atomic layer A513 and the heterogeneous zones A5131.

As shown in FIG. 22 specifically, it is a top plan view of the double-layer artificial 2D material A5 and as shown in FIG. 21 specifically, it is a sectional view taken along line A-A of FIG. 22. It is understood that an artificial double-layer 2D material having heterogeneous zones is not limited to that shown in FIG. 21; and further, an artificial double-layer 2D material is not limited to have two heterogeneous zones A5131 as shown in FIG. 21 or FIG. 22. An artificial double-layer 2D material having heterogeneous zones can be made depending on different manufacturing steps and different electronic components. The embodiment is only exemplary. An ordinary person skilled in the art can manufacture an artificial double-layer 2D material including a layer having a plurality of heterogeneous junctions using the method of the invention. The produced artificial double-layer 2D material can be used to manufacture rectifiers, integrated circuits and semiconductor devices including FETs.

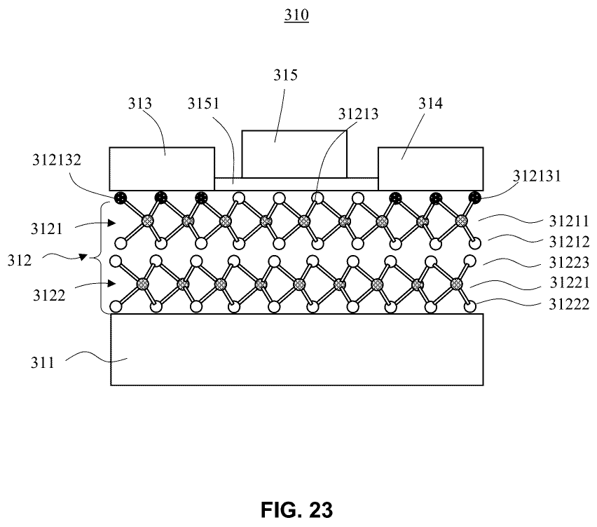

Referring to FIG. 23, it is a schematic longitudinal sectional view of an electronic component (e.g., FET) A310 according to a fourth configuration of the invention, the electronic component A310 incorporating the artificial double-layer 2D material (MoS₂) of the invention. It is noted that the artificial double-layer 2D material can be a different chemical compound in other embodiments. In the embodiment, the electronic component A310 includes a substrate A311, an artificial double-layer 2D material layer A312, a source A312, a drain A314 and a gate A315. The artificial double-layer 2D material layer A312 includes a first layered atomic structure A3121 and a second layered atomic structure A3122. The first layered atomic structure A3121 includes a first middle atomic layer A31211, a first lower atomic layer A31212 and a first upper atomic layer A31213 in which the first lower atomic layer A31212 and the first upper atomic layer A312123 are disposed on lower and upper surfaces of the first middle atomic layer A31211 respectively. The second layered structure A3122 includes a second middle atomic layer A31221, a second lower atomic layer A31222 and a second upper atomic layer A31223 in which the second lower atomic layer A31222 and the second upper atomic layer A31223 are disposed on lower and upper surfaces of the second middle atomic layer A31221 respectively. The upper atomic layer A31213 is heterogeneous and includes a first heterogeneous zone A312131 and a second heterogeneous zone A312132 spaced from the first heterogeneous zone A312131. In the embodiment, the first and second heterogeneous zones A312131, A312132 each implemented as a metal atomic layer. The source A3 13 is provided on the second heterogeneous zone A312132 and the drain A314 is provided on the first heterogeneous zone A312131 respectively. Each of the source 313 and the drain 314 is metallic electrode. Thus, the source A313 is electrically connected to the metal atomic layer of the second heterogeneous zone A312132 by means of metallic bonding and the drain A314 is electrically connected to the metal atomic layer of the first heterogeneous zone A312131 by means of metallic bonding respectively.

A method of manufacturing the electronic component A310 of FIG. 23 comprises depositing an insulating layer on the substrate A311 using chemical vapor deposition (CVD) or atomic layer deposition (ALD) wherein the insulating layer includes SiO₂, Si₂N₃, Al₂O₃, Hf₂O₃ and BN or CaF; forming an artificial double-layer 2D material layer A312 as a semiconductor channel material, using first photolithography to create minutely patterned thin films of suitable materials over the artificial double-layer 2D material layer A312; using etching (e.g., plasma etching) to chemically remove layers from the surface of artificial double-layer 2D material layer A312; using second photolithography to create minutely patterned thin films (e.g., the source A313 and the drain A314) of suitable materials over the artificial double-layer 2D material layer A312; using photoresist to form a patterned coating on the surface of the artificial double-layer 2D material layer A312 wherein the second heterogeneous zone A312132 under the source A313 and the first heterogeneous zone A312131 under the drain A314 are exposed respectively; using hydrogen plasma to remove atomic layers so as to form an Mo—S structure; metalizing wherein electronic beam evaporation is performed on the above metals so as to deposit a metal atomic layer on each of the first heterogeneous zone A312131 and the second heterogeneous zone A312132, thereby forming an M—Mo—S 2D alloy material layer thereon; forming the source A313 and the drain A314 on the n M—Mo—S 2D alloy material layer; forming a gate insulating layer A3151 including SiO₂, Al₂O₃, Hf₂O₃, and BN or CaF on the artificial double-layer 2D material layer A 312; and finally using photolithography and deposition to form the gate A315 on the gate insulating layer A3151, thereby producing the electronic component A310.

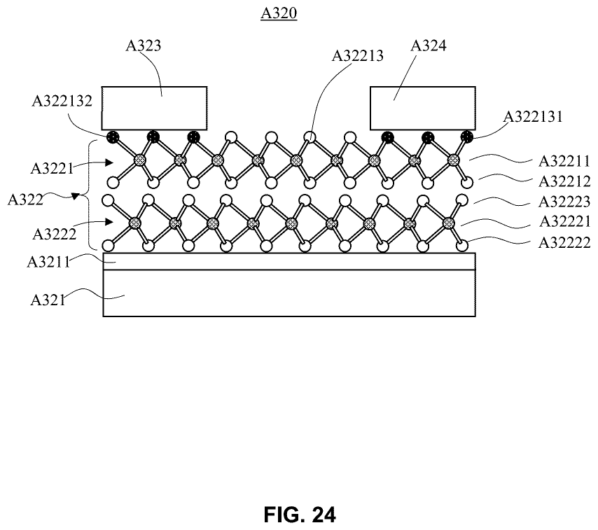

Referring to FIG. 24, it is a schematic longitudinal sectional view of an electronic component A320 according to a fifth configuration of the invention, the electronic component 320 incorporating the artificial double-layer 2D material of the invention. The electronic component A320 is implemented as a back-gated FET in which a highly doped substrate A321 (e.g., P⁺⁺ or N⁺⁺Si) is used as a fin. The method of manufacturing the electronic component A320 comprises depositing a gate insulating layer A3211 (e.g., Al₂O₃, SiO₂, nitride, or fluoride (e.g., CaF)); forming the artificial double-layer 2D material layer A322 comprises a first layered atomic structure A3221 and a second layered atomic structure A3222. The first layered atomic structure A3221 includes a first middle atomic layer A32211, a first lower atomic layer A32212, and a first upper atomic layer A32213 in which the first lower atomic layer A32212, and the first upper atomic layer A32213 are disposed on lower and upper surfaces of the firs middle atomic layer A32211 respectively. The second layered atomic structure A3222 includes a second middle atomic layer A32221, a second lower atomic layer A32222, and a second upper atomic layer A32223 in which the second lower atomic layer A32222, and the second upper atomic layer A32223 are disposed on lower and upper surfaces of the second middle atomic layer A32221 respectively. The first upper atomic layer A32213 is heterogeneous and includes a first heterogeneous zone A322131 and a second heterogeneous zone A322132 spaced from the first heterogeneous zone A322131. In the embodiment, the first and second heterogeneous zones A322131, A322132 each implemented as a metal atomic layer. The source A323 is provided on the second heterogeneous zone A322132 and the drain A324 is provided on the first heterogeneous zone A322131 respectively. Each of the source A323 and the drain A324 is metallic electrode. Thus, the source A323 is electrically connected to the metal atomic layer of the second heterogeneous zone A322132 by means of metallic bonding and the drain A324 is electrically connected to the metal atomic layer of the first heterogeneous zone A322131 by means of metallic bonding respectively. The method of manufacturing the electronic component A320 further comprises the steps of using photolithography and deposition to form the channel on the gate insulating layer A3211; finally using hydrogen plasma to remove the upper metal layers, materials using ALE and then conjugation with metal both based on the source A323 and the drain A324, thereby producing the electronic component A320.

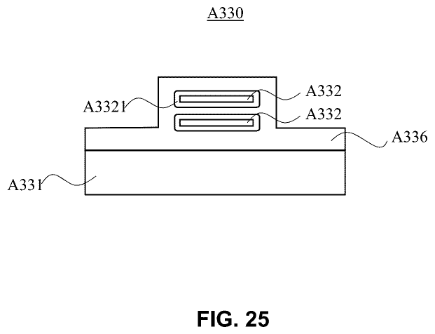

Referring to FIG. 25, it is a schematic longitudinal sectional view of an electronic component 330 according to a sixth configuration of the invention, the electronic component A330 incorporating the artificial double-layer 2D material of the invention. The electronic component A330 may be an electron encircling gate field-effect transistor. The electronic component A330 includes a substrate A331, a gate A336 provided on the substrate A331, a plurality of (two are shown) spaced, staked artificial double-layer 2D material layers A332 in the gate A336, and a plurality of (two are shown) gate insulating layers (e.g., oxide layers or layers made of an insulator material such as nitride or fluoride) A3321 in the gate A336 and each wrapped around the artificial double-layer 2D material layer A332. In the sixth configuration, a TMD is staked in MoS₂/oxide/MoS₂/oxide. Next, reactive-ion etching (RIE) is used to define source/drain and contact and remove deposited materials to form the defined pattern with MoS₂ nanosheets exposed. It is noted that in above method the insulating layer in 2D nanosheet is required to remove. Finally, use ALD to fill drive-in metal precursor in the metal gate A336 which wraps around the 2D channels. It is understood that various heterostructures including 2D semiconductor and metal junctions, insulator oxides, and 2D semiconductor devices (e.g., PRAM, rectifiers, etc.) by taking advantage of above two principles.

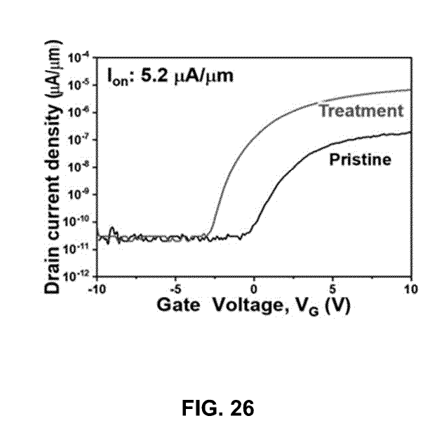

Referring to FIG. 26, FIG. 26 plots gate voltage (V) versus drain current density (μA/μm) for an electronic component formed of artificial 2D material of the invention with or without plasma treatment as comparison. Under the same channel material conditions, interface treatment at the S/D metal contact regions resulted in significant electrical improvements. The Iₒₙ of double-layer MoS₂ increased from 9.65×10⁻⁴ μA/μm to 2.26×10⁻² μA/μm, and the electron mobility increased by 21 times. After low-damage plasma treatment for 3 minutes, Iₒₙ enhanced to 4.47×10⁻¹ μA/μm, and the electron mobility improved by 50 times compared to the monolayer. Additionally, hydrogen plasma treatment caused a notable N-type doping effect on Vth, indicating that interface-treated 2D metallization achieved an ideal carrier injection junction, thereby enhancing device performance. The characteristic of double-layer 2D material is that the lower MoS₂ layer is protected by the upper MoS₂ layer. This protection prevents atomic-scale defects, structural damage, or doping effects to the MoS₂ channel during the deposition of gate oxide layers, thereby avoiding degradation or modulation of its intrinsic electrical properties. Similarly, during the deposition of source/drain electrodes and the removal of portions of the first upper atomic layer using plasma to form MoS, the structure of the lower MoS₂ layer is not damaged. Thus, the overall benefit is the formation of an interface layer without damaging electrical properties of the lower MoS₂ layer.

The impact of annealing treatment on the characteristics of Ti—Mo—S semiconductor device is provided in the invention. The Ti—Mo—S semiconductor device without plasma treatment shows improved contact resistance after annealing, but its stability is poor, and its electrical characteristics are suboptimal (low on/off ratio, low mobility, and high subthreshold swing). As a comparison, the Ti—Mo—S semiconductor device has been treated by plasma and has been processed by annealing, demonstrates superior electrical stability with high on-off ratio, high carrier mobility and low subthreshold swing.

The artificial 2D material having a plurality of heterogeneous junctions of the invention has the following advantages and benefits in comparison with TMDs of the conventional art: Improved performance, higher controllability of electronic components, lower contact resistance, lower energy consumption, higher efficiency and higher integration.

An artificial double-layer 2D material provided in the invention has excellent physical and chemical properties for manufacturing semiconductors, compared to a monolayer 2D material. When removing the S atomic layer using plasma, prolonged plasma bombardment can directly damage the MoS₂ structure. The removal process not only removes the S atomic layer but also create defects in the Mo structure. Therefore, a double-layer MoS₂ is used to improve this issue. The upper layer of MoS₂ acts as a protective layer to reduce defects caused by plasma bombardment and metal deposition. This ensures that the lower layer of the double-layer MoS₂ maintains an intact atomic structure without destructive damage, thereby preserving its electronic properties.

While the invention has been described in terms of preferred embodiments, those skilled in the art will recognize that the invention can be practiced with modifications within the spirit and scope of the appended claims.

What is claimed is:

1. An artificial double-layer two-dimensional material, comprising:
a first layered atomic structure, comprising a first middle atomic layer, a first lower atomic layer, and a first upper atomic layer, the first lower and the first upper atomic layers being disposed on lower and upper surfaces of the first middle atomic layer respectively, the first middle atomic layer being a two-dimensional (2D) planar atomic structure formed of a transition metal; the first lower and the first upper atomic layers being 2D planar atomic structures formed of heterogeneous atoms;
a second layered atomic structure, comprising a second middle atomic layer, a second lower atomic layer, a second upper atomic layer, the second lower and the second upper atomic layers being disposed on lower and upper surfaces of the second middle atomic layer respectively, the second middle atomic layer being a two-dimensional (2D) planar atomic structure formed of a transition metal; and
wherein atoms of the first layered atomic structure and the second layered atomic structure are bound by chemical bonding, the first layered atomic structure and the second layered atomic structure are bound by van der Waals forces.

2. The artificial double-layer two-dimensional material as claimed in claim 1, wherein the transition metal is selected from the group consisting of tungsten (W), molybdenum (Mo), titanium (Ti), platinum (Pt), indium (In), tin (Sn), niobium (Nb), and tantalum (Ta).

3. The artificial double-layer two-dimensional material as claimed in claim 2, wherein the first lower atomic layer, the second lower atomic layer and the second upper atomic layer are formed of sulfur(S), selenium (Se), or tellurium (Te).

4. The artificial double-layer two-dimensional material as claimed in claim 3, wherein the first upper atomic layer includes a plurality of metal atoms.

5. The artificial double-layer two-dimensional material as claimed in claim 4, wherein the metal of the first upper atomic layer is selected from the group consisting of cobalt (Co), nickel (Ni), tungsten (W), copper (Cu), titanium (Ti), palladium (Pd), bismuth (Bi), antimony (Sb), scandium (Sc), vanadium (V), gold (Au), and platinum (Pt).

6. The artificial double-layer two-dimensional material as claimed in claim 5, further comprising an outer atomic layer disposed on the first upper atomic layer, the outer atomic layer being bound by metallic bonding and the outer atomic layer including a plurality of metal atoms.

7. The artificial double-layer two-dimensional material as claimed in claim 6, wherein the metal of the outer atomic layer is selected from the group consisting of cobalt (Co), nickel (Ni), tungsten (W), copper (Cu), titanium (Ti), palladium (Pd), bismuth (Bi), antimony (Sb), scandium (Sc), vanadium (V), gold (Au), and platinum (Pt).

8. The artificial double-layer two-dimensional material as claimed in claim 3, wherein the chemical element of the first upper atomic layer is selected from the group consisting of carbon (C), oxygen (O), nitrogen (N), fluorine (F), sulfur(S), selenium (Se), chlorine (Cl), and phosphorus (P).

9. The artificial double-layer two-dimensional material as claimed in claim 8, further comprising an outer atomic layer disposed on the first upper atomic layer, the outer atomic layer including a plurality of metal atoms.

10. The artificial double-layer two-dimensional material as claimed in claim 9, wherein the metal of the outer atomic layer is selected from the group consisting of cobalt (Co), nickel (Ni), tungsten (W), copper (Cu), titanium (Ti), palladium (Pd), bismuth (Bi), antimony (Sb), scandium (Sc), vanadium (V), gold (Au), and platinum (Pt).

11. The artificial double-layer two-dimensional material as claimed in claim 1, wherein the artificial 2D material does not belong to the metallic properties (1T phase).

12. A method for manufacturing the artificial double-layer two-dimensional material as claimed in claim 11, comprising:
providing at least two artificial two-dimensional materials each having a layered atomic structure; stacking the two-dimensional materials each having a layered atomic structure to form a double-layer two-dimensional material having a two-layered atomic structure;
placing the double-layer two-dimensional material in a vacuum;
removing an atomic layer on one surface of the double-layer 2D material to expose unsaturated compounds by means of plasma;
introducing heterogeneous atoms into the vacuum wherein the heterogeneous atoms are different from atoms on the other surface of the double-layer material; and
binding the heterogeneous atoms with the unsaturated compounds to form an artificial double-layer 2D material having two heterogeneous junctions.

13. A field-effect transistor comprising:
a substrate having an oxide layer, the artificial double-layer 2D material claimed in claim 11 disposed on the substrate, a first metallic electrode and a second metallic electrode;
wherein the first upper atomic is heterogeneous and comprises a first heterogeneous zone and a second heterogeneous zone; the first and second heterogeneous zones each is a metal atomic layer; the first metallic electrode is electrically connected to the metal atomic layer of the second heterogeneous zone by means of metallic bonding and the second metallic electrode is electrically connected to the metal atomic layer of the first heterogeneous zone by means of metallic bonding respectively.

14. The field-effect transistor as claimed in claim 13, wherein the metal contact of the interface between the first metallic electrode and the first heterogeneous zone, as well as between the second metallic electrode and the second heterogeneous zone are carrier doping regions.

15. The field-effect transistor as claimed in claim 13, wherein the metal contact of the interface between the first metallic electrode and the first heterogeneous zone, as well as between the second metallic electrode and the second heterogeneous zone match the electronic structure of the first middle atomic layer, reducing the resistance of carrier injection.

16. The field-effect transistor as claimed in claim 13, wherein the metal contact of the interface between the first metallic electrode and the first heterogeneous zone, as well as between the second metallic electrode and the second heterogeneous zone, form dipole internal electric fields, reducing the resistance of carrier injection.
